(19) United States
(12) Patent Application Publication
(10) Pub. No.: US 2002/0130335 A1
(43) Pub. Date: Sep. 19, 2002

(54) Semiconductor device for detecting neutron, and method for the fabrication

(75) Inventor: Takashi Inbe, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 09/960,356

(22) Filed: Sep. 24, 2001

(30) Foreign Application Priority Data
Mar. 13, 2001 (JP) 2001-070071

(51) Int. Cl. H01L 27/148

(52) U.S. Cl. 257/225

(57) ABSTRACT

A semiconductor integrated device includes a boron containing layer 4 containing an isotope ¹⁰B formed on a semiconductor substrate 1. Neutrons irradiated to the boron containing layer 4 are brought into a reaction with the isotope ¹⁰B to emit α rays which are then rushed into the semiconductor substrate 1 to generate electron-positive hole pairs 8 in a P-N junction layer. Thus, neutrons are detected.

### BACKGROUND OF THE INVENTION

1. Field of the Invention

The present invention relates to a semiconductor device and a method for its fabrication, and more specifically to a semiconductor device for detection of radiation.

2. Description of the Prior Art

There is known a neutron detection method by a BF₃ counter or by radio-activation of a metal thin film. Such a prior art method suffers from a difficulty that an apparatus itself is large-sized because the size of the counter is bulky. Another difficulty is that is the real time measurement for a neutron field is difficult. Further, a prior art semiconductor detector costs very high.

### SUMMARY OF THE INVENTION

The present invention is made to solve the difficulties with the prior art, and it is a first object of the present invention to provide a semiconductor device and its fabrication method that is suitable for neutron detection with small-size and less cost.

A second object of the present invention is to provide a semiconductor device, and its fabrication method, capable of instantaneously monitoring and analyzing detected neutron.

According to one aspect of the present invention, a semiconductor device for detecting a neutron comprises a semiconductor substrate and a boron containing layer containing isotope ¹⁰B and being formed on said semiconductor substrate.

In another aspect, in the semiconductor device, a PN junction is formed on a surface area of said semiconductor substrate below said boron containing layer.

In another aspect, in the semiconductor device, an analyzing circuit portion is formed on said semiconductor substrate in a region other than the region where said neutron is detected.

According to another aspect of the present invention, in a method for fabricating a semiconductor device for detecting a neutron, a predetermined impurity is doped into a first region on a semiconductor substrate to form a PN junction on a surface region of said semiconductor substrate. An analyzing circuit section is formed in a second region of said semiconductor substrate for analyzing detected neutron. A boron containing layer that contains an isotope ¹⁰B is formed on said semiconductor substrate in at least said first region.

Other and further objects, features and advantages of the invention will appear more fully from the following description.

### BRIEF DESCRIPTION OF THE DRAWINGS

FIG. 1 is a cross sectional view illustrating an arrangement of a semiconductor device according to a first preferred embodiment of the present invention;

FIG. 2 is a perspective view illustrating the semiconductor device according to the first embodiment of the present invention; and

FIG. 3 is a schematic cross sectional view illustrating the arrangement of a semiconductor device according to a second embodiment of the present invention.

### DETAILED DESCRIPTION OF THE PREFERRED EMBODIMENTS

In what follows, several preferred embodiments of the present invention will be described with reference to the accompanying drawings.

First Embodiment

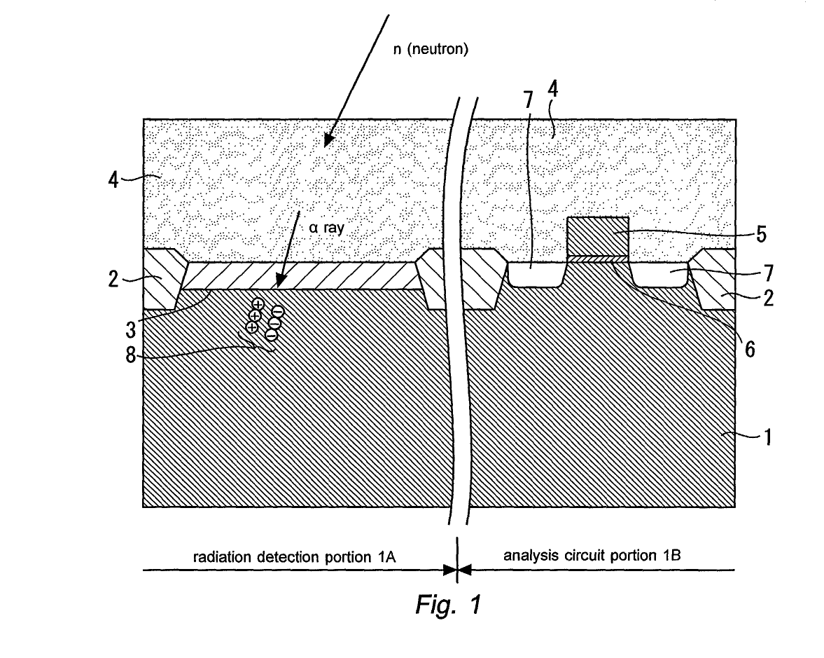

Referring to FIG. 1, there is illustrated, in a schematic cross section view, a semiconductor radiation detector according to a first embodiment of the present invention. The semiconductor device is an one chip type neutron detector. As illustrated in FIG. 1, the semiconductor device includes two regions of a radiation detection portion 1A and an analysis circuit portion 1B assembled in the semiconductor substrate.

The radiation detection portion 1A serves as a detector for detecting an incident neutron. In the radiation detection portion 1A, an N type impurity diffusion layer is formed on a surface area of a P type silicon semiconductor substrate 1 defined by a device isolation oxide film 2, and a PN junction is formed between the diffusion layer and the P type silicon semiconductor substrate 1. A depletion layer is formed in a predetermined region adjacent the PN junction 3.

On the other hand, in the analysis circuit portion 1B, a gate oxide film 6 and a gate electrode 5 are formed on the P type silicon semiconductor substrate 1. An impurity diffusion layer 7 is formed as source/drain in the surface region of the P type silicon semiconductor substrate 1 on opposite sides of the gate electrode 5. Thus, a MOS transistor is formed all together. In the analysis circuit portion 1B, there is formed a circuit for analyzing radiation rays detected in the radiation detection section 1A with the aid of a circuit in combination of such a MOS transistor and other elements.

The circuit in the analysis circuit portion 1B is constructed by properly combining several fundamental circuits such as an amplifier circuit for amplifying a fine signal, a single channel height analyzer circuit for selecting only a pulse with particular height, a simultaneous counting circuit for investing temporal coincidence between pulses of 2 systems, a scaler circuit for counting the number of pulses, and a multiple height analyzer circuit for automatically analyzing pulse height distribution.

There is formed a boron containing layer 4 on the P type silicon semiconductor substrate 1 in the radiation detection portion 1A and the analysis circuit portion 1B. In the boron containing layer 4 isotope ¹⁰B are contained in a predetermined ratio other than boron B that are stable isotope.

Isotope ¹⁰B is generally contained by about 20% in natural boron. In the semiconductor device according to the present embodiment, isotope ¹⁰B with predetermined concentration or more is contained in the boron containing layer 4.

In the following, there will be described a method for fabricating the semiconductor device according to the first embodiment. A device isolation oxide film 2 is first formed on a P type silicon semiconductor substrate 1 with the aid of the so-called LOCOS method and STI method, etc., to define a device active area. An N type impurity is doped into the device active area by ion implantation for example to form a PN junction with respect to the P type silicon semiconductor substrate

In contrast, in the analysis circuit section 1B, a gate oxide film 6 and a gate electrode 5 are formed on the P type silicon semiconductor substrate 1, and an impurity diffusion layer 7 is formed on the P type silicon semiconductor substrate 1 on opposite sides of the gate electrode 5 by doping an N type impurity. In the analysis circuit section 1B, an analysis circuit is formed with devices such as MOS transistors and the like including the impurity diffusion layer 7 and the gate electrode 5. A boron containing layer 4 is thereafter formed on the P type silicon semiconductor substrate in the radiation detection section 1A and the analysis circuit section 1B to ensure the arrangement shown in FIG. 1.

For the formation of the boron containing layer 4 there are known a several method. In one method, boron is simultaneously doped into a film formed by a CVD method. In another method, an interlayer insulating film is formed and then boron is doped by ion implantation. The degree of radiation-activity by neutron depends upon the number of isotopes ¹⁰B existent in the boron containing layer 4. Accordingly, even if the concentration of the isotope ¹⁰B in the boron containing layer 4 is low, it may be sufficient that the boron containing layer 4 is formed to be thicker. Inversely, when the concentration of the isotope ¹⁰B in the boron containing layer 4 is high, the boron containing layer 4 can be made thin. Particularly, provided the concentration of the isotope ¹⁰B in the boron containing layer 4 is set to fall within about 10²⁰/cm³ to 10²³/cm³, and more preferably provided the upper limit of the concentration is set to 10²²/cm³ or less, the neutron and ¹⁰B are securely brought into reaction to effectively emit α rays.

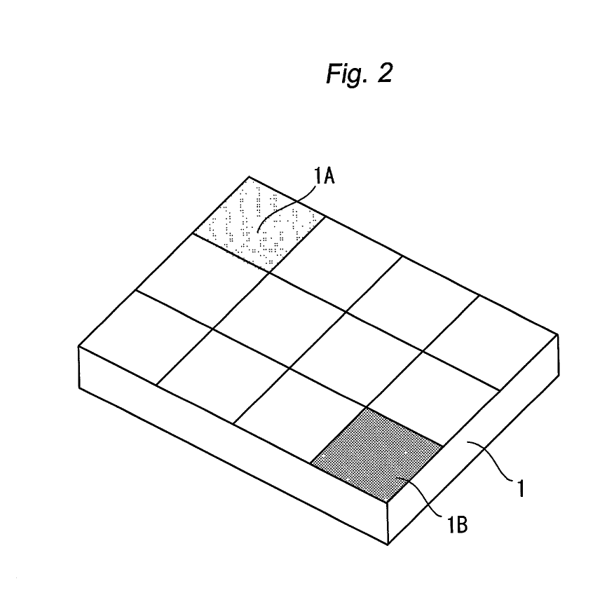

Referring now to FIG. 2, there is provided a perspective view illustrating the arrangement of a semiconductor device according to the first embodiment. As illustrated in FIG. 2, in the semiconductor device according to the first embodiment, the region on the P type silicon semiconductor substrate 1 is divided into a plurality of regions, and hence the radiation detection portion 1A and the analysis circuit portion 1B are disposed at diagonal positions to each other. Provided the radiation detection portion 1A and the analysis circuit portion 1B are separated away, irradiation of neutron can be limited to the region of the radiation detection section 1A for example, so that occurrence of soft error which might be caused by α rays emitted onto the P type silicon semiconductor substrate 1 of the analyzing circuit section 1B can be suppressed to the minimum.

In the following, there will be described the principle and operation of the neutron detection in the semiconductor device according to the first embodiment. First, the radiation detection section 1A is irradiated with neutron that is an object to be detected. Thereupon, the isotope ¹⁰B in the boron containing layer 4 and the irradiated neutron are brought into reaction to cause ¹⁰B (n, α) ⁷Li reaction in the boron containing layer 4. Hereby, α rays are emitted from the boron containing layer 4 toward the lower layer P type silicon semiconductor substrate 1.

The emitted α rays rush into the P type silicon semiconductor substrate 1 of the radiation detection section 1A to generate an electron-positive hole pair 8 in a depletion layer in the vicinity of an interface 3 of the PN junction or in the vicinity of the depletion layer as illustrated in FIG. 1. Generation of the electron-positive hole pair 8 is achieved in response to the degree of emission of the α rays, so that the α rays can be detected by collecting electric charges of the electron-positive hole pair 8 generated in the PN junction region. It is therefore possible to estimate the degree of emission of α rays and hence the number of irradiated neutrons by detecting a current flowing through the PN junction.

More specifically, pulsation of a current flowing through the PN junction can be amplified on the basis of the amount of electric charges collected from the depletion layer, and hence energy spectrum of α rays can be estimated with the aid of counting or by measuring peak height distribution. It is therefore possible to estimate the number and properties of the irradiated neutrons by analyzing the current flowing through the PN junction.

The analysis circuit portion 1B has a function to achieve the aforementioned analysis from the amount of collected electric charges. The analysis circuit portion 1B is disposed on the same substrate as the radiation detection portion 1A , i.e., on the same chip, whereby the aforementioned analysis is instantaneously achieved after the electric charges due to the electron-positive hole pair 8 are collected, and incident neutron rays can be monitored instantaneously. Since the present device extending from the radiation detection portion 1A as a reaction portion for neutrons to the analysis circuit portion 1B for analyzing collected electric charges has been formed on the one chip, the whole of the neutron detection system can be constructed into a very small structure.

According to the first embodiment of the present invention, as described above, α rays are emitted toward the P type silicon semiconductor substrate 1 with the aid of a reaction between the isotope ¹⁰B in the boron containing layer 4 and the irradiated neutrons, by which the electron-positive hole pair 8 are generated in the vicinity of the PN junction of the P type silicon semiconductor substrate 1. Therefore, it is possible to estimate the number of irradiated neutrons and properties of the neutrons such as energy spectrum by detecting and analyzing the amount of electric charges due to the electron-positive hole pair 8.

Further, both of the radiation detection portion 1A and the analysis circuit portion 1B are provided on the semiconductor substrate 1, whereby neutron rays can be instantaneously monitored, and therefore highly accurate neutron detection is achieved in the state where disturbance to a neutron field as an object to be measured is reduced to the utmost. Further, the present device extending from the radiation detection portion 1A to the analysis assembled circuit portion 1B is formed on the one chip, so that it is possible to provide the neutron detection system wherein the detector is sharply miniaturized and the cost is greatly reduced.

It is herein noticed that a nuclide to emit α rays is not limited to ¹⁰B, and any nuclide having a property to emit α rays as a result of its reaction with any neutron may be employed instead of ¹⁰B. There is preferably desired any nuclide that achieves a (n, α) reaction with a neutron and that further has a relatively larger reaction cross section for neutron, for example nuclides such as Li (⁶Li, etc) are useable instead of ¹⁰B.

Second Embodiment

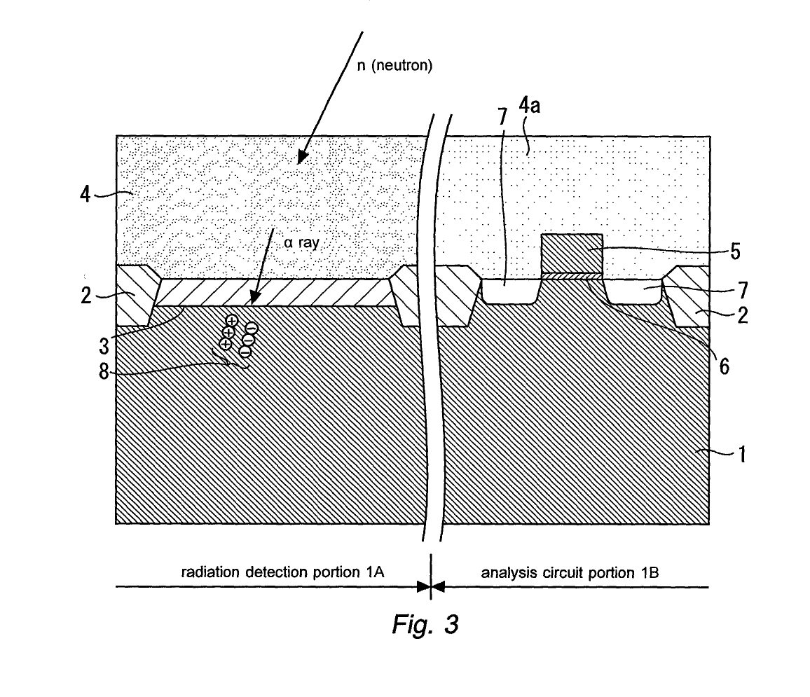

Referring to FIG. 3, there is illustrated, in a schematic cross sectional view, a semiconductor type radiation detector according to the second embodiment of the present invention. The semiconductor device according to the second embodiment is different from the first one in that the former forms a boron containing layer 4a in the analysis circuit portion 1B having lower ¹⁰B concentration than that of the boron containing layer 4 in the radiation detection portion 1A. Since the other arrangements of the semiconductor device according to the second embodiment are the same as those in the first embodiment, in the description of FIG. 3 the same symbols as those in FIG. 1 shall be applied to the same constituent components as those illustrated in FIG. 1 and the description will be partly omitted.

Provided the boron containing layer 4a having lower ¹⁰B concentration is formed on the P type silicon semiconductor substrate 1 in the analysis circuit portion 1B as described above, it is possible to suppress ¹⁰B (n, α) ⁷Li reaction in the vicinity of the analysis circuit portion 1B upon irradiation of neutrons, and it is possible to reduce the probability where α rays run into the P type silicon semiconductor substrate 1 in the analysis circuit portion 1B.

Although α rays rushing into the semiconductor substrate might cause soft error for the circuit, it is possible in the analysis circuit portion 1B to reduce the rushing of α rays by reducing the ¹⁰B concentration, and it is further possible to reduce to the utmost erroneous operation that might be caused by soft error of an analysis circuit constructed in the analysis assembled circuit portion 1B to the utmost.

The semiconductor device according to the second embodiment is fabricated by forming the PN junction on the P type silicon semiconductor substrate 1 of the radiation detection portion 1A in the same fashion as in the first embodiment, and forming devices such as MOS transistors that are composed of the gate electrode 5 and the impurity diffusion layer 7 in the analysis circuit portion 1B, and further forming the boron containing layers 4, 4b on the P type silicon semiconductor substrate 1. Thereupon, in order to set the ¹⁰B concentration of the boron containing layer 4b to be lower than that of the boron containing layer 4 upon the formation of the boron containing layers 4, 4b, the loadings of boron in the analysis circuit portion 1B is more reduced than in the radiation detection portion 1A. When ¹⁰B is doped into the boron containing layers 4, 4b by ion implantation, the kinds of ions are discriminated in accordance with masses of atoms in the ion implantation, and hence only ¹⁰B that is an isotope can be doped at a necessary position by applying a resist mask, and hence the ¹⁰B concentration is made low partly to form the boron containing layer 4b. It is further possible not to dope ¹⁰B at an unnecessary portion by making use of the resist mask. Further, provided that the method for doping ¹⁰B upon the film formation with a CVD method is employed, it may be plausible that simultaneously with the formation of the interlayer insulating film with a CVD method, ¹⁰B is doped at high concentration to form the boron containing layer 4, and then the boron containing layer 4 in the region where the boron containing layer 4b is formed is removed with photolithography and successive dry etching. Thereafter, simultaneously with the formation of the interlayer insulating film with a CVD method, ¹⁰B is doped at low concentration to form the boron containing layer 4b.

In accordance with the second embodiment of the present invention, as described above, concentration of ¹⁰B doped into the boron containing layer 4 is adapted to have a distribution thereof on the same chip, and in the analysis circuit portion 1B, a boron containing layer 4a having lower ¹⁰B concentration than that of the boron containing layer 4 in the radiation detection portion A is formed on the P type silicon semiconductor substrate 1. Thereby, α rays are prevented from rushing into the P type silicon semiconductor substrate 1 in the vicinity of the analysis circuit portion 1B and hence soft error resistance is improved. Further, a layer not containing ¹⁰B may be formed on the P type silicon semiconductor substrate 1 in the analysis circuit portion 1B. Hereby, α rays can be prevented from being generated to the utmost and hence soft error is prevented from occurring. The device according to the present invention is useable as a detector even for a neutron field of a higher dose by improving the soft error resistance in the analysis assembled circuit portion 1B.

Although in the aforementioned embodiment, electron-hole pairs 8 are generated in the vicinity of an interface 3 of the PN junction with α rays to detect the number of neutrons based upon the amount of electric charges of the pairs, the amount of α rays may be directly detected.

The present invention may be applied to measurements for radiations other than neutrons by employing a nuclide X that causes an X (β, α) Y reaction (X, Y represent particular nuclei) instead of B, i.e., by employing a reaction where β rays and a nucleus X cause a nucleus reaction to produce α rays and a new nucleus Y. Likewise, the present invention may be applicable to measurements of radiations other than neutrons also by employing a nuclide X that causes an X(γ, α)Y reaction (X, Y represent specific nuclei) instead of B, i.e., by employing a reaction where γ rays and the nucleus X cause a nuclear reaction to produce α rays and a new nucleus Y.

The features and advantages of the present invention may be summarized as follows.

In accordance with the present invention, a neutron and an isotope ¹⁰B are brought into reaction to emit α rays, and hence the number of neutrons can be detected based upon the dose of α rays highly accurately by forming on a semiconductor substrate a boron containing layer containing the isotopes ¹⁰B.

Electron-positive hole pairs are formed in a depletion layer of the PN junction by emitted α rays, whereby the amount of electric charges of the electron-positive hole pairs can be estimated from a current flowing through the PN junction and therefore the number of neutrons can be detected from the estimated amount of electric charges.

An analysis circuit comprising a predetermined semiconductor device is formed on the semiconductor device in other regions than a region where any neutron is detected, and the electric charges due to generated electron-positive hole pairs are analyzed, whereby the region to detect any neutron and the analysis circuit portion are disposed on the same chip, whereby neutron rays can be instantaneously monitored, and hence any neutron can be detected highly accurately in the state where turbulence to a neutron field that is an object to be measured is reduced to the utmost. Further, the region where any neutron is detected and the analysis circuit portion are formed on the one chip, whereby the radiation detector can be sharply miniaturized and the cost can be greatly reduced.

Furthermore, in another aspect, concentration of an isotope ¹⁰B in the boron containing layer in the analysis circuit portion is adapted to be more reduced than that of isotope ¹⁰B in the boron containing layer in the region where any neutron is detected, whereby emission of α rays can be suppressed to a minimum and hence occurrence of soft error can be reduced to the utmost in the analysis circuit portion.

Furthermore, in another aspect, no boron containing layer is provided in the analysis circuit portion, whereby emission of α rays in the analysis circuit portion, and hence occurrence of soft error can be suppressed to a minimum.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2001-70071, filed on Mar. 13, 2001 including specification, claims, drawings and summary, on which the Convention priority of the present application is based, are incorporated herein by reference in its entirety.

What is clamed is:

1. A semiconductor device for detecting a neutron comprising:
a semiconductor substrate; and
a boron containing layer containing isotope ¹⁰B, the layer being formed on said semiconductor substrate.

2. A semiconductor device according to claim 1, further comprising a PN junction formed on a surface area of said semiconductor substrate below said boron containing layer; wherein
an electron-positive hole pair are generated in a depletion layer of said PN junction by a ray generated by a reaction between said neutron and said isotope ¹⁰B; and
the neutrons is detected on the basis of the quantity of electric charge of the electron-positive hole pairs.

3. A semiconductor device according to claim 2, further comprising an analyzing circuit portion including a predetermined semiconductor element on said semiconductor substrate in a region other than the region where said neutron is detected.

4. A semiconductor device according to claim 3, wherein the concentration of said isotope ¹⁰B in said boron containing layer in said analyzing circuit portion is lower than that of said isotope ¹⁰B of said boron containing layer in the region where said neutron is detected.

5. A semiconductor device according to claim 3, wherein no boron containing layer is provided on said analyzing circuit portion.

6. A method for fabricating a semiconductor device for detecting a neutron comprising the steps of:
doping a predetermined impurity into a first region on a semiconductor substrate to form a PN junction on a surface region of said semiconductor substrate;
forming an analyzing circuit section in a second region of said semiconductor substrate for analyzing detected neutron; and
forming a boron containing layer that contains an isotope ¹⁰B that reacts with said neutron to generate an α ray on said semiconductor substrate in at least said first region.

7. A method for fabricating a semiconductor device according to claim 6, wherein said boron containing layer is formed on said semiconductor substrate in said first and second regions, and
said concentration of said isotope ¹⁰B in said second region is lower than that of said isotope ¹⁰B in the first region.

8. A method for fabricating a semiconductor device according to claim 6, wherein said boron containing layer is formed only on said semiconductor substrate in said first region.
